(19) United States
(12) Patent Application Publication
(10) Pub. No.: US 2026/0214890 A1
(43) Pub. Date: Jul. 23, 2026

(54) SEMICONDUCTOR MEMORY DEVICE, METHOD OF OPERATING THE SAME AND ELECTRONIC SYSTEM INCLUDING THE SAME

(71) Applicant: Samsung Electronics Co., Ltd., Suwon-si (KR)

(72) Inventors: Chulkwon Park, Suwon-si (KR); Young Seok Park, Suwon-si (KR); Kyu-Chang Kang, Suwon-si (KR); Hoseok Lee, Suwon-si (KR)

(21) Appl. No.: 19/273,536

(22) Filed: Jul. 18, 2025

(30) Foreign Application Priority Data
Jan. 23, 2025 (KR) 10-2025-0009944

(51) Int. Cl. H10B 12/00; G11C 11/408; H10B 80/00

(52) U.S. Cl. CPC H10B 12/50; G11C 11/4085; H10B 80/00

(57) ABSTRACT

A semiconductor memory device includes a first semiconductor die and a second semiconductor die. The second semiconductor die is stacked on the first semiconductor die in a vertical direction. The first semiconductor die includes a first connection pad, a second connection pad, a first wordline, and a second wordline. The first wordline is electrically connected to the first connection pad. The second wordline is electrically connected to the second connection pad. The second semiconductor die includes a first sub-wordline driver and a second sub-wordline driver. The first sub-wordline driver is spaced apart from the first connection pad in the vertical direction. The second sub-wordline driver is spaced apart from the second connection pad in the vertical direction and drives the first wordline through the first connection pad.

### CROSS-REFERENCE TO RELATED APPLICATION(S)

This application claims priority under 35 U.S.C. § 119 to Korean Patent Application No. 10-2025-0009944 filed on Jan. 23, 2025, in the Korean Intellectual Property Office, the disclosure of which is incorporated by reference herein in its entirety.

### BACKGROUND

To increase a storage capacity and the degree of integration of a semiconductor memory

device, in particular, a volatile memory device, memory cells may be arranged a three-dimensional structure. A periphery on cell (POC) structure or a cell on periphery (COP) structure may include peripheral circuits for the memory cells that are disposed on or under the memory cells. In these structures, sub-wordline drivers of the semiconductor memory device may be electrically connected to wordlines through vertical connection structures and connection pads to drive corresponding wordlines. When driving the wordlines, threshold voltages of transistors of the sub-wordline drivers may be affected by fluctuations in voltage levels of the vertical connection structures, thereby making the voltage levels of the wordlines unstable.

### SUMMARY

Implementations of the present disclosure provide a semiconductor memory device decreasing fluctuations in threshold voltages of transistors of sub-wordline drivers such that voltage levels of wordlines are stabilized.

Implementations of the present disclosure provide an operating method of the semiconductor memory device.

Implementations of the present disclosure provide an electronic system including the semiconductor memory device.

According to some implementations, a semiconductor memory device includes a first semiconductor die, and a second semiconductor die. The second semiconductor die is stacked on the first semiconductor die in a vertical direction. The first semiconductor die includes, a first connection pad, a second connection pad, a first wordline, and a second wordline. The first wordline is electrically connected to the first connection pad. The second wordline is electrically connected to the second connection pad. The second semiconductor die includes a first sub-wordline driver and a second sub-wordline driver. The first sub-wordline driver is disposed to be spaced apart from the first connection pad in the vertical direction. The second sub-wordline driver is disposed to be spaced apart from the second connection pad in the vertical direction and drives the first wordline through the first connection pad.

According to some implementations, in an operating method of a semiconductor memory device, a read command and a read address is received.

The first wordline is activated by the second sub-wordline driver based on wordline driving information. First subsequent operations after the activation of the first wordline are performed. A read operation based on the read command is completed.

According to some implementations, an electronic system includes a host device, and a semiconductor memory device. The semiconductor memory device operates under control of the host device. The semiconductor memory device includes a first semiconductor die, and a second semiconductor die. The second semiconductor die is stacked on the first semiconductor die in a vertical direction. The first semiconductor die includes a first connection pad, a second connection pad, a first wordline, and a second wordline. The first wordline is electrically connected to the first connection pad. The second wordline is electrically connected to the second connection pad. The second semiconductor die includes a first sub-wordline driver and a second sub-wordline driver. The first sub-wordline driver is disposed to be spaced apart from the first connection pad in the vertical direction. The second sub-wordline driver is disposed to be spaced apart from the second connection pad in the vertical direction and drives the first wordline through the first connection pad.

### BRIEF DESCRIPTION OF THE DRAWINGS

The above and other objects and features of the present disclosure will become apparent by describing in detail implementations thereof with reference to the accompanying drawings.

FIG. 1 is a diagram illustrating a semiconductor memory device according to some implementations of the present disclosure.

FIGS. 2 and 3 are diagrams illustrating some implementations of a semiconductor memory device of FIG. 1.

FIG. 4A is a diagram illustrating a connection relationship between one wordline and one of sub-wordline drivers of FIG. 3.

FIG. 4B is a timing diagram for describing an operation of sub-wordline driver of FIG. 4A.

FIG. 4C is a diagram for describing some implementations of the placement of transistors included in a sub-wordline driver of FIG. 4A.

FIG. 5A is a diagram illustrating a connection relationship between sub-wordline drivers and wordlines according to a comparative example of the present disclosure. FIG. 5B is a diagram illustrating a connection relationship between sub-wordline drivers and vertical connection structures in the connection relationship of FIG. 5A.

FIGS. 6A and 6B are diagrams illustrating a connection relationship between sub-wordline drivers and wordlines according to some implementations of the present disclosure. FIG. 6C is a diagram illustrating a connection relationship between sub-wordline drivers and vertical connection structures in the connection relationships of FIGS. 6A and 6B.

FIGS. 7 and 8 are flowcharts illustrating an operating method of a semiconductor memory device according to some implementations of the present disclosure.

FIGS. 9, 10, 11, 12, 13, 14, 15, and 16 are diagrams illustrating a connection relationship between sub-wordline drivers and vertical connection structures in a semiconductor memory device according to some implementations of the present disclosure.

FIG. 17 is a block diagram illustrating some implementations of a semiconductor memory device of FIG. 1.

FIG. 18 is a structure diagram illustrating some implementations of a semiconductor package including a semiconductor memory device according to implementations of the present disclosure.

FIG. 19 is a conceptual diagram illustrating an electronic system including a semiconductor memory device according to implementations of the present disclosure.

### DETAILED DESCRIPTION

Below, implementations of the present disclosure will be described in detail and clearly to such an extent that one skilled in the art easily carries out the present disclosure.

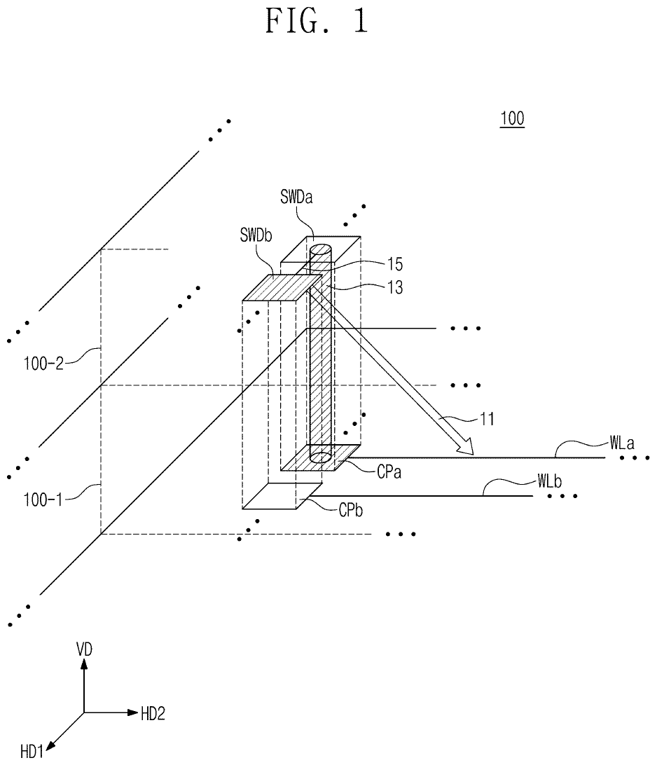

FIG. 1 is a diagram illustrating a semiconductor memory device according to some implementations of the present disclosure.

In FIG. 1, horizontal directions HD1 and HD2 and a vertical direction VD which are perpendicular to each other may be defined. Below, the directions HD1, HD2, and VD are used consistently.

Referring to FIG. 1, a semiconductor memory device 100 may be a volatile memory device. Below, the volatile memory device may be a dynamic random access memory (DRAM), but this is provided only as an example. In some implementations, the semiconductor memory device 100 may be an arbitrary semiconductor memory device identical or similar in structure to the DRAM.

The semiconductor memory device 100 may include a first semiconductor die 100-1 and a second semiconductor die 100-2 stacked on the first semiconductor die in the vertical direction VD. For example, the semiconductor memory device 100 may have a periphery on cell (POC) structure in which peripheral circuits for memory cells are disposed on the memory cells. However, the scope of the present disclosure is not limited thereto. For example, the semiconductor memory device 100 may have a cell on periphery (COP) structure.

The first semiconductor die 100-1 may include a memory cell array, and the second semiconductor die 100-2 may include a plurality of sub-wordline drivers. The memory cell array may include a plurality of memory cells which are connected to a plurality of wordlines and a plurality of bitlines and arranged in rows and columns. The plurality of sub-wordline drivers may drive the plurality of wordlines.

The first semiconductor die 100-1 may further include a plurality of connection pads respectively connected to the plurality of wordlines. The plurality of sub-wordline drivers may be disposed to be spaced apart from the plurality of connection pads in the vertical direction VD and may drive the corresponding wordlines through the plurality of connection pads. For example, the plurality of sub-wordline drivers may be respectively disposed at locations being perfectly or exactly vertical to the plurality of connection pads. For example, one wordline may be electrically connected to one connection pad, and one sub-wordline driver may be electrically connected to one connection pad to drive one wordline. For example, the number of the plurality of sub-wordline drivers may be equal to the number of the plurality of connection pads, but the scope of the present disclosure is not limited thereto.

The first semiconductor die 100-1 and the second semiconductor die 100-2 may further include a plurality of vertical connection structures. The plurality of vertical connection structures may extend in the vertical direction VD and may connect the plurality of sub-wordline drivers and the plurality of connection pads. For example, one wordline may be electrically connected to one connection pad, and one sub-wordline driver may be electrically connected to one vertical connection structure and one connection pad such that one sub-wordline drives one wordline. For example, one connection pad, one vertical connection structure, and one sub-wordline driver may be sequentially disposed on a vertical line extending in the vertical direction VD.

In some implementations, the plurality of connection pads may include a first connection pad CPa and a second connection pad CPb, and the plurality of wordlines may include a first wordline WLa and a second wordline WLb. For example, the first wordline WLa may be electrically connected to the first connection pad CPa, and the second wordline WLb may be electrically connected to the second connection pad CPb.

In some implementations, the plurality of sub-word line drivers may include a first sub-wordline driver SWDa and a second sub-wordline driver SWDb. For example, the first sub-wordline driver SWDa may be disposed to be spaced apart from the first connection pad CPa in the vertical direction VD, and the second sub-wordline driver SWDb may be disposed to be spaced apart from the second connection pad CPb in the vertical direction VD. For example, the first sub-wordline driver SWDa may be disposed at a location being perfectly or exactly vertical to the first connection pad CPa, and the second sub-wordline driver SWDb may be disposed at a location perfectly or exactly vertical to the second connection pad CPb.

In some implementations, the second sub-wordline driver SWDb may drive the first wordline WLa through the first connection pad CPa (e.g., 11). For example, the semiconductor memory device 100 may further include a vertical connection structure (e.g., 13) extending in the vertical direction VD from the first connection pad CPa, and the second sub-wordline driver SWDb may be connected to an end (e.g., 15) of the vertical connection structure to drive the first wordline WLa. For example, when the semiconductor memory device 100 is implemented such that the first wordline WLa is driven by the first sub-wordline driver SWDa, not the second sub-wordline driver SWDb, threshold voltages of transistors included in the first sub-wordline driver SWDa may be affected by fluctuations in a voltage level of the vertical connection structure extending in the vertical direction VD from the first connection pad CPa, thereby making the voltage level of the first wordline WLa to be driven unstable.

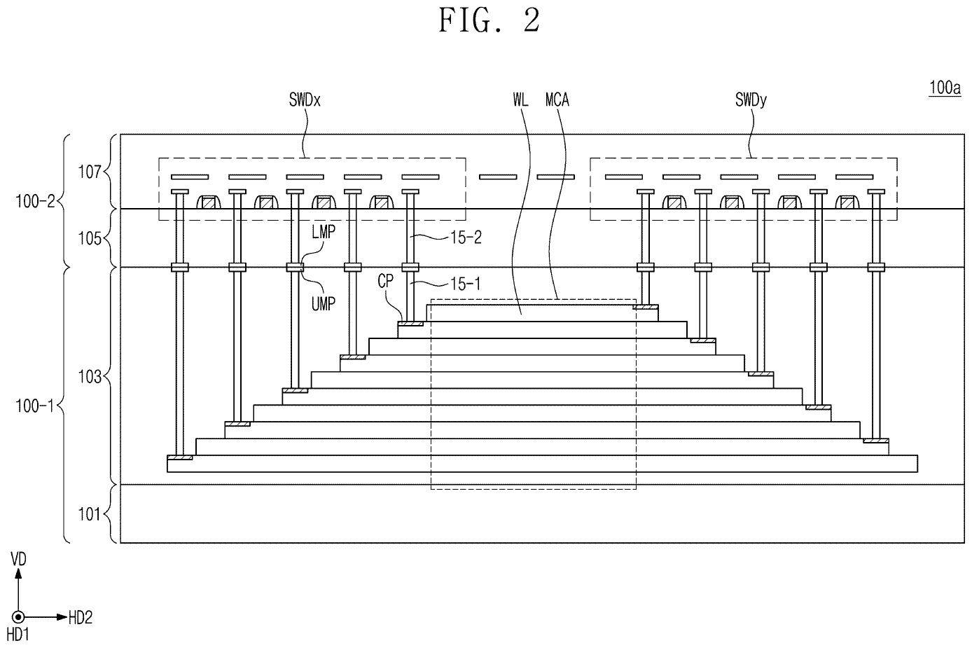

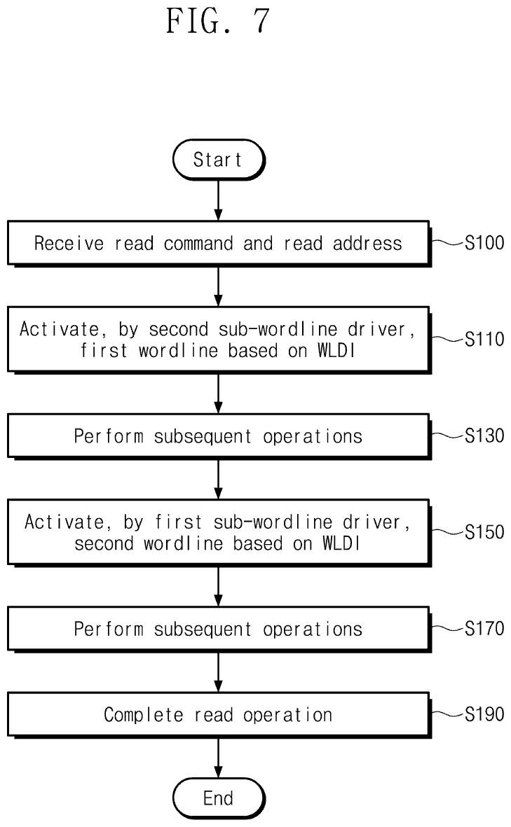

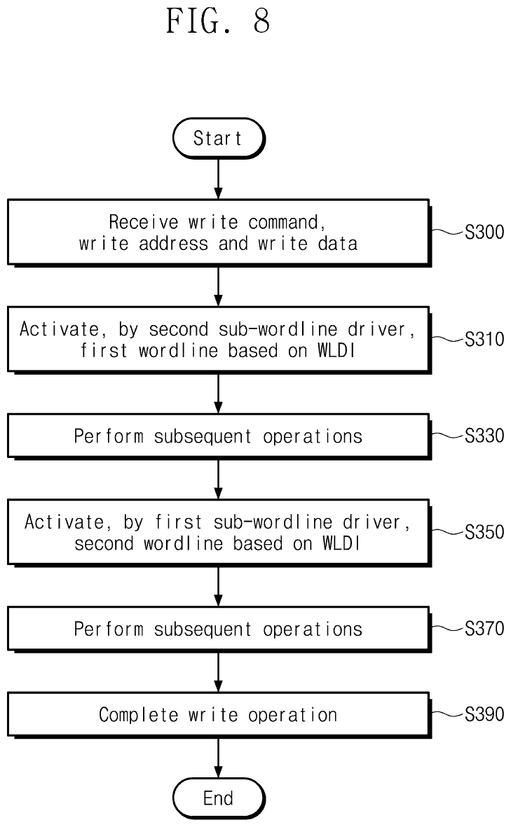

According to the above configuration, a semiconductor memory device according to implementations of the present disclosure may drive a wordline by using any other sub-wordline driver, not a sub-wordline driver located in a direction perpendicular to a connection pad connected to the wordline. Accordingly, a sub-wordline driver driving the wordline may be disposed to be spaced apart from an upper portion of the connection pad connected to the wordline to be driven, and thus, a voltage level of the wordline to be driven may be stabilized even though the voltage level of the vertical connection structure fluctuates. A connection relationship between sub-wordline drivers and wordlines or connection relationships between sub-wordline drivers and vertical connection structures will be described with reference to FIGS. 2, 6A, 6B, 6C, and 9 to 15. An operating method of a semiconductor memory device will be described with reference to FIGS. 7 and 8.

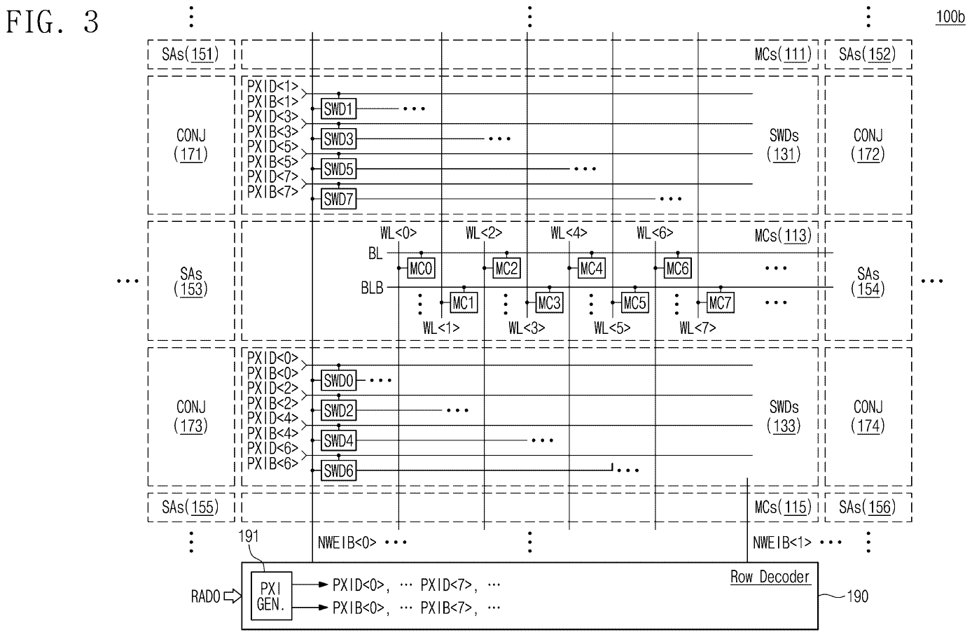

FIGS. 2 and 3 are diagrams illustrating some implementations of a semiconductor memory device of FIG. 1.

Referring to FIG. 2, a semiconductor memory device 100a may correspond to the semiconductor memory device 100 of FIG. 1.

The semiconductor memory device 100a may include the first semiconductor die 100-1 and the second semiconductor die 100-2 stacked on the first semiconductor die 100-1 in the vertical direction VD.

In some implementations, the first semiconductor die 100-1 may include a first substrate 101 and a first insulating layer 103, and the second semiconductor die 100-2 may include a second substrate 105 and a second insulating layer 107.

In some implementations, the first insulating layer 103 may include a plurality of wordlines WLs and a plurality of first connection structures 15-1 and may further include a memory cell array MCA and a plurality of bitlines. The memory cell array MCA may include a plurality of memory cells each including a cell transistor and a cell capacitor. The plurality of memory cells may be connected to the plurality of wordlines WLs and the plurality of bitlines. The plurality of wordlines WLs may be respectively connected to the plurality of connection pads CPs. The plurality of first connection structures 15-1 may extend in the vertical direction VD from the plurality of connection pads CPs.

In some implementations, the second substrate 105 and the second insulating layer 107 may include a plurality of sub-wordline drivers SWDx and SWDy and a plurality of second connection structures 15-2. The plurality of second connection structures 15-2 may extend in the vertical direction VD from the plurality of sub-wordline drivers SWDx and SWDy.

In some implementations, a plurality of upper metal patterns UMPs may be formed on an upper portion of the first insulating layer 103, and a plurality of lower metal patterns LMPs may be formed on a lower portion of the second substrate 105 to correspond to the plurality of upper metal patterns UMPs. The plurality of first connection structures 15-1 may be electrically connected to the plurality of upper metal patterns UMPs, and the plurality of second connection structures 15-2 may be electrically connected to the plurality of lower metal patterns LMPs. The plurality of upper metal patterns UMPs may be exposed on the upper portion of the first insulating layer 103, and the plurality of lower metal patterns LMPs may be exposed on the lower portion of the second substrate 105. In this case, the plurality of upper metal patterns UMPs and the plurality of lower metal patterns LMPs may contact each other. However, the scope of the present disclosure is not limited thereto. In other implementations, the plurality of upper metal patterns UMPs may be formed on the upper portion of the first insulating layer 103, the plurality of lower metal patterns LMPs may not be formed on the lower portion of the second substrate 105, and the plurality of upper metal patterns UMPs may be electrically connected directly to the plurality of second connection structures 15-2.

In some implementations, the plurality of sub-wordline drivers SWDx and SWDy may be respectively connected to the plurality of wordlines WLs through the plurality of second connection structures 15-2, the lower metal patterns LMPs, the upper metal patterns UMPs, the plurality of first connection structures 15-1, and the plurality of connection pads CPs and thus may drive the plurality of wordlines WLs through the components. For example, one of the plurality of second connection structures 15-2, one of the lower metal patterns LMPs, one of the upper metal patterns UMPs, and one of the plurality of first connection structures 15-1 may correspond to the vertical connection structure described with reference to FIG. 1. For example, the first connection structures 15-1 may be “wordline contact vias”, and the second connection structures 15-2 may be “through silicon vias”. However, the scope of the present disclosure is not limited thereto.

Referring to FIG. 3, a semiconductor memory device 100b may correspond to the semiconductor memory device 100 of FIG. 1. The semiconductor memory device 100b may include memory cells (or “memory cell array”) 111, 113, and 115, sub-wordline drivers 131 and 133, sense amplifier blocks 151, 152, 153, 154, 155, and 156, conjunction circuits 171, 172, 173, and 174, and a row decoder 190. The row decoder 190 may include a control signal generator 191.

The row decoder 190 may receive a row address RADO and may generate signals for driving selected memory cells among the memory cells 111, 113, and 115. For example, based on the row address RADO, the row decoder 190 may generate one or more of wordline enable signals NWEIB<0>, NWEIB<1>, etc. and one or more of sub-wordline driver control signals PXID<0>, . . . , PXID<7> . . . , PXIB<0>, . . . , PXIB<7>, etc. and may drive the selected memory cells.

In some implementations, the row decoder 190 may generate one or more of the wordline enable signals NWEIB<0>, NWEIB<1>, etc. based on first bits of the row address RADO, and the control signal generator 191 included in the row decoder 190 may generate one or more of the sub-wordline driver control signals PXID<0>, . . . , PXID<7> . . . , PXIB<0>, . . . , PXIB<7>, etc. based on second bits of the row address RADO. For example, when a result of decoding the first bits and the second bits of the row address RADO indicates the case of driving one or more of memory cells MC0, MC1, MC2, MC3, MC4, MC5, MC6, and MC7, the row decoder 190 may generate the wordline enable signal NWEIB<0>. In the case of driving one or more (e.g., MC0, MC2, MC4, and MC6) of the memory cells MCo to MC7, the control signal generator 191 may generate one or more (e.g., PXID<0>, PXIB<0>, PXID<2>, PXIB<2>, PXID<4>, PXIB<4>, PXID<6>, and PXIB<6>) of the sub-wordline driver control signals PXID<0>, . . . , PXID<7> . . . , PXIB<0>, . . . , PXIB<7>, etc. In this case, sub-wordline drivers SWD0, SWD2, SWD4, and SWD6 may activate wordlines WL<0>, WL<2>, WL<4>, and WL<6> based on the wordline enable signal NWEIB<0> and the sub-wordline driver control signals PXID<0>, PXIB<0>, PXID<2>, PXIB<2>, PXID<4>, PXIB<4>, PXID<6>, and PXIB<6>.

The conjunction circuits 171 to 174 may include metal lines for supplying a power to the sense amplifier blocks 151 to 156, the sub-wordline drivers 131 and 133, and the memory cells 111, 113, and 115 or providing electrical signals generated therefrom, and may include various circuits for any other operations of the semiconductor memory device 100b.

For convenience of description, eight memory cells MC0 to MC7 and wordline enable signals and sub-wordline driver control signals for driving the eight memory cells MC0 to MC7 are illustrated in FIG. 3, but the number of wordlines, the number of wordline enable signals, and the number of sub-wordline driver control signals are provided only as an example. The numbers of wordline enable signals and sub-wordline driver control signals for driving a given number of memory cells may also be variously changed depending on a way to drive memory cells.

Each of the sub-wordline drivers SWD0, SWD1, SWD2, SWD3, SWD4, SWD5, SWD6, and SWD7 may include a pull-up transistor, a pull-down transistor, and a keeping transistor. Drain contacts of the pull-up transistor, the pull-down transistor, and the keeping transistor included in one sub-wordline driver may be electrically connected to a vertical connection structure located on one side of a sub-wordline driver adjacent thereto or spaced apart therefrom as much as a given distance.

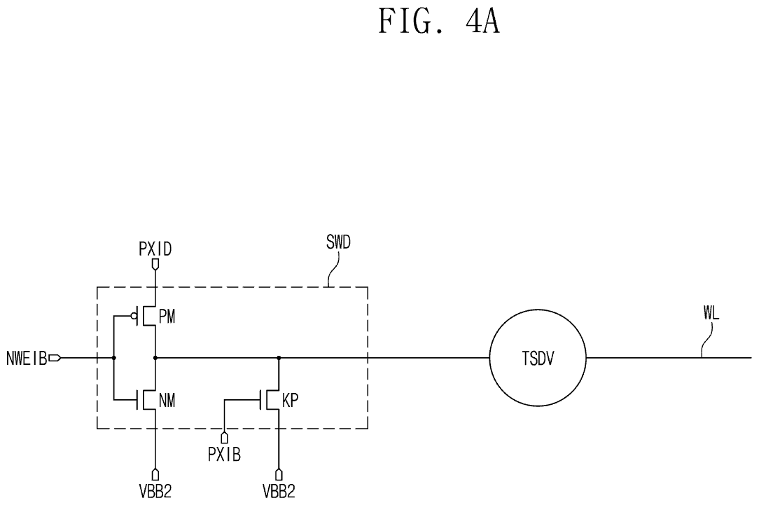

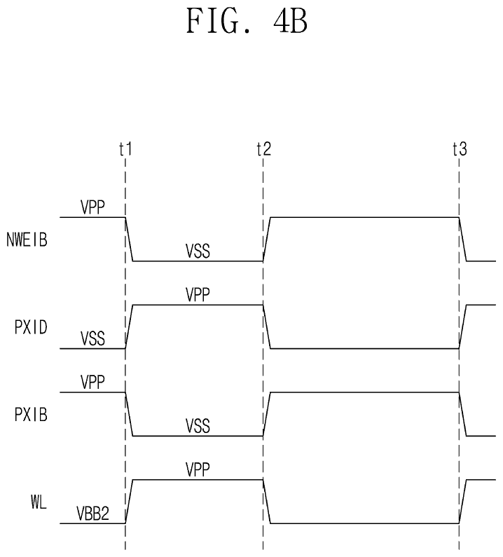

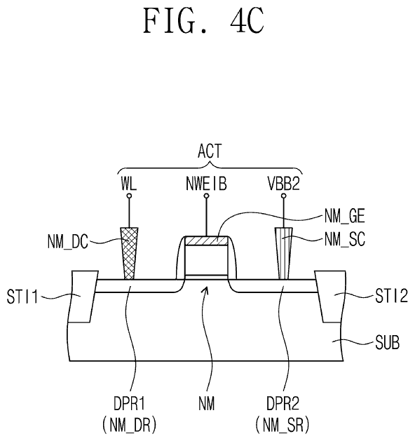

FIG. 4A is a diagram illustrating a connection relationship between one wordline and one of sub-wordline drivers of FIG. 3.

Referring to FIG. 4A, a sub-wordline driver SWD may include a pull-up transistor PM, a pull-down transistor NM, and a keeping transistor KP. The sub-wordline driver SWD may drive the wordline WL through a vertical connection structure TSDV (or a connection pad connected thereto).

An activation interval and a deactivation interval of the wordline WL may be defined. The activation interval may be an interval in which the wordline WL maintains a first voltage level to drive selected memory cells in each of operation modes (e.g., a read operation mode, a write operation mode, and a self-refresh operation mode) of a semiconductor memory device. The deactivation interval may be an interval in which the wordline WL maintains a second voltage level lower than the first voltage level such that unselected memory cells are not driven in each of the operation modes of the semiconductor memory device. The activation interval and the deactivation interval may be respectively referred to as a “driving time interval” and a “non-driving time interval”.

In the activation interval of the wordline WL, the pull-up transistor PM may pull up the wordline WL. For example, in the activation interval of the wordline WL, the pull-up transistor PM may be turned on based on a wordline enable signal NWEIB and a control signal PXID, and thus, the wordline WL may be pulled up to a high voltage VPP corresponding to the first voltage level.

In the deactivation interval of the pull-down transistor NM, the pull-down transistor NM may pull down the wordline WL based on the wordline enable signal NWEIB, and in the deactivation interval of the wordline WL, the keeping transistor KP may maintain the voltage level of the pulled-down wordline WL based on a control signal PXIB. For example, in the deactivation interval of the wordline WL, the pull-down transistor NM may be turned on such that the wordline WL is pulled down to a negative voltage VBB2 corresponding to the second voltage level, and the keeping transistor KP may be turned on such that the voltage level of the wordline WL thus pulled down is maintained at the negative voltage VBB2.

FIG. 4B is a timing diagram for describing an operation of sub-wordline driver of FIG. 4A.

Voltage levels of the wordline enable signal NWEIB, the control signals PXID and PXIB, and the wordline WL are illustrated in FIG. 4B. The voltage levels of the signals illustrated in FIG. 4B may be associated with a sub-wordline driver activating the wordline WL.

Referring to FIGS. 4A and 4B, the wordline enable signal NWEIB and the control signals PXID and PXIB may have one of a voltage level VPP and a voltage level VSS. The voltage level VPP may be a signal level sufficient to turn off the pull-up transistor PM and to turn on the pull-down transistor NM, and the voltage level VSS may be a signal level sufficient to turn on the pull-up transistor PM and to turn off the pull-down transistor NM. The wordline WL may have one of the voltage level VPP and a voltage level VBB2. The voltage level VPP may be a high voltage level sufficient to activate the wordline WL, and the voltage level VBB2 may be a low voltage level sufficient to deactivate the wordline WL.

The wordline enable signal NWEIB may have the voltage level VPP before t1, may transition to the voltage level VSS at t1, and may maintain the voltage level VSS until t2. Also, the wordline enable signal NWEIB may transition to the voltage level VPP at t2 and may maintain the voltage level VPP until t3.

The control signal PXID may have the voltage level VSS before t1, may transition to the voltage level VPP at t1, and may maintain the voltage level VPP until t2. Also, the control signal PXID may transition to the voltage level VSS at t2 and may maintain the voltage level VSS until t3. When the control signal PXID has the voltage level VSS, the control signal PXIB may have the voltage level VPP; when the control signal PXID has the voltage level VPP, the control signal PXIB may have the voltage level VSS.

Before t1 or between t2 and t3, because the wordline enable signal NWEIB has the voltage level VPP and the control signal PXIB has the voltage level VPP, the pull-down transistor NM and the keeping transistor KP may be turned on, and the voltage level of the wordline WL may indicate the negative voltage VBB2.

Between t1 and t2 or after t3, because the wordline enable signal NWEIB has the voltage level VSS and the control signal PXIB has the voltage level VSS, the pull-up transistor PM may be turned on, and the voltage level of the wordline WL may indicate the voltage level VPP being the voltage level of the control signal PXID.

Between t1 and t2, the wordline WL may be activated. Before t1 or between t2 and t3, the wordline WL may be deactivated.

As described with reference to FIG. 4B, the activation interval and the deactivation interval may be defined based on the wordline WL. The time interval from t1 to t2 may correspond to the activation interval of the wordline WL, and the time interval from t2 to t3 may correspond to the deactivation interval of the wordline WL.

FIG. 4C is a diagram for describing some implementations of the placement of transistors included in a sub-wordline driver of FIG. 4A.

The pull-down transistor NM of the sub-wordline driver SWD illustrated in FIG. 4A is illustrated in FIG. 4C.

Referring to FIGS. 4A and 4C, in a semiconductor substrate SUB, an active region ACT placed between device isolation layers STI1 and STI2 may be defined, and doping regions DPR1 and DPR2 may be formed in the active region ACT.

The pull-down transistor NM may receive the wordline enable signal NWEIB through a gate electrode NM_GE and may include a drain contact NM_DC connected to the wordline WL and a source contact NM_SC connected to a terminal for providing the negative voltage VBB2. The doping region DPR1 connected to the drain contact NM_DC may be referred to as a “drain region NM_DR”, and the doping region DPR2 connected to the source contact NM_SC may be referred to as a “source region NM_SR”.

The pull-up transistor PM and the keeping transistor KP may be configured to be similar to the pull-down transistor NM. Accordingly, each of the pull-up transistor PM and the keeping transistor KP may receive corresponding signals through a gate electrode, a drain contact, and a source contract.

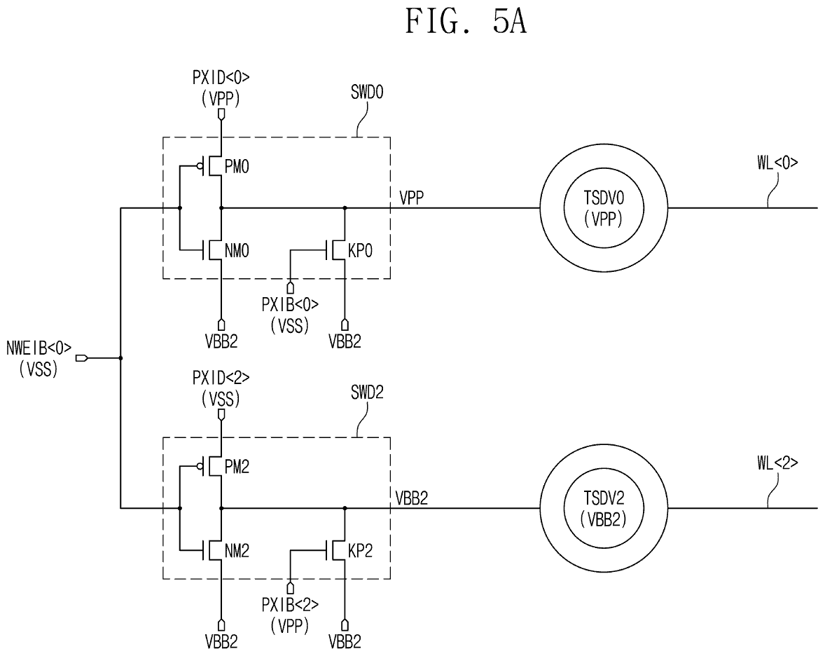

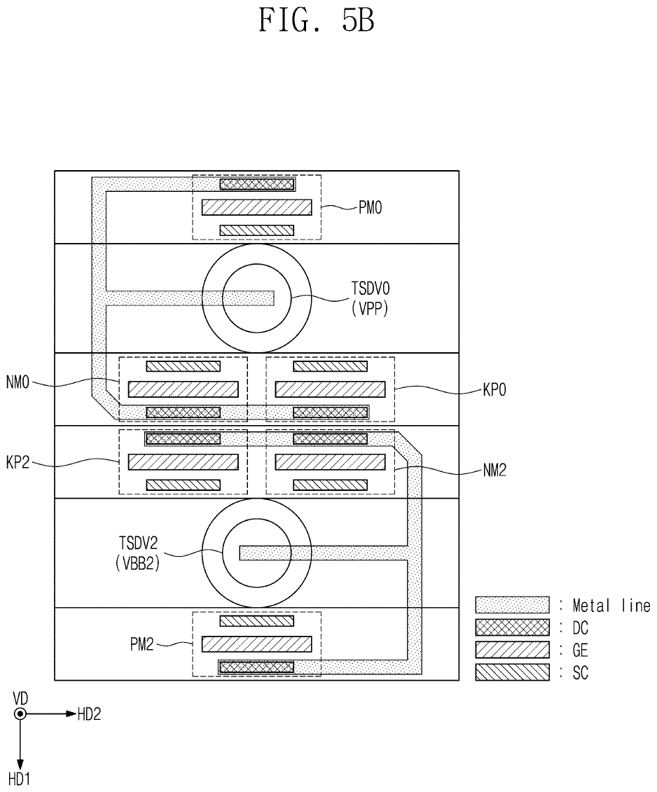

FIG. 5A is a diagram illustrating a connection relationship between sub-wordline drivers and wordlines according to a comparative example of the present disclosure. FIG. 5B is a diagram illustrating a connection relationship between sub-wordline drivers and vertical connection structures in the connection relationship of FIG. 5A.

Referring to FIG. 5A, in comparative examples of the present disclosure, a sub-wordline driver placed in a direction perpendicular to a connection pad connected to a wordline to be driven may drive the wordline. For example, in the case of intending to activate the wordline WL<0>, the remaining wordline WL<2> except for the wordline WL<0> may be deactivated.

For example, the sub-wordline driver SWD0 may be placed in a direction perpendicular to a connection pad connected to the wordline WL<0> and may activate the wordline WL<0> through a vertical connection structure TSDV0, and the sub-wordline driver SWD2 may be placed in a direction perpendicular to a connection pad connected to the wordline WL<2> and may deactivate the wordline WL<2> through a vertical connection structure TSDV2. Voltage levels of the wordline enable signal NWEIB<0> and the control signals PXID<0> and PXIB<0> for the activation may be the same as those described with reference to FIG. 4B. In this case, referring to FIGS. 5A and 5B, when the vertical connection structure TSDV0 has the voltage level VPP, a channel voltage of a pull-up transistor PM0 of the sub-wordline driver SWD0 and a channel voltage of a pull-down transistor NM0 of the sub-wordline driver SWD0 may be increased; as a result, the threshold voltage of the pull-up transistor PM0 may increase, and the threshold voltage of the pull-down transistor NM0 may decrease. As in the above description, when the vertical connection structure TSDV2 has the voltage level VBB2, a channel voltage of a pull-up transistor PM2 of the sub-wordline driver SWD2 and a channel voltage of a pull-down transistor NM2 of the sub-wordline driver SWD2 may be decreased; as a result, the threshold voltage of the pull-up transistor PM2 may decrease, and the threshold voltage of the pull-down transistor NM2 may increase.

For example, the increase in the threshold voltage of the pull-up transistor PM0 and the decrease in the threshold voltage of the pull-down transistor NM0 may cause the decrease in an activation speed (e.g., the increase in a rising time) of the wordline WL<0>, and the decrease in the threshold voltage of the pull-up transistor PM2 and the increase in the threshold voltage of the pull-down transistor NM2 may cause the decrease in a deactivation speed (e.g., the increase in a falling time) of the wordline WL<2>.

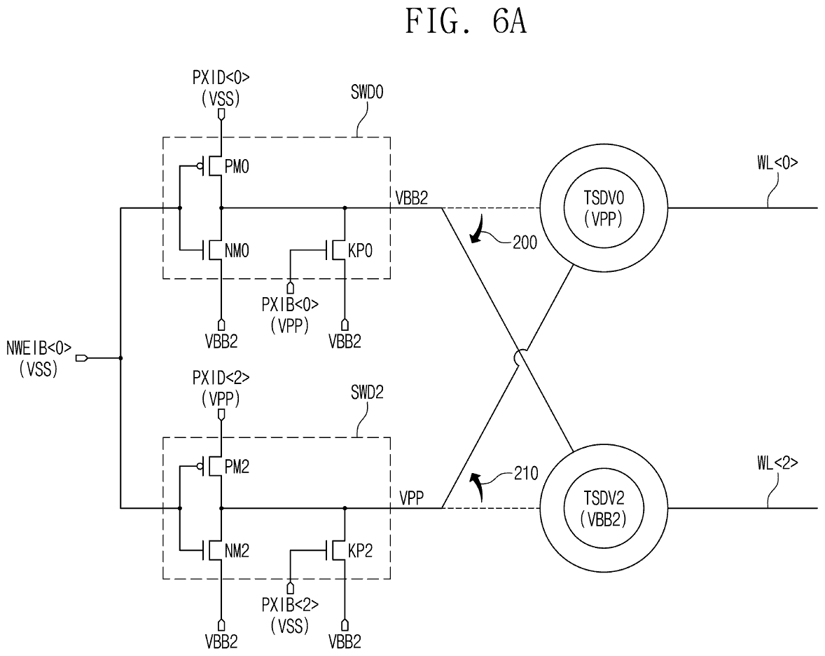

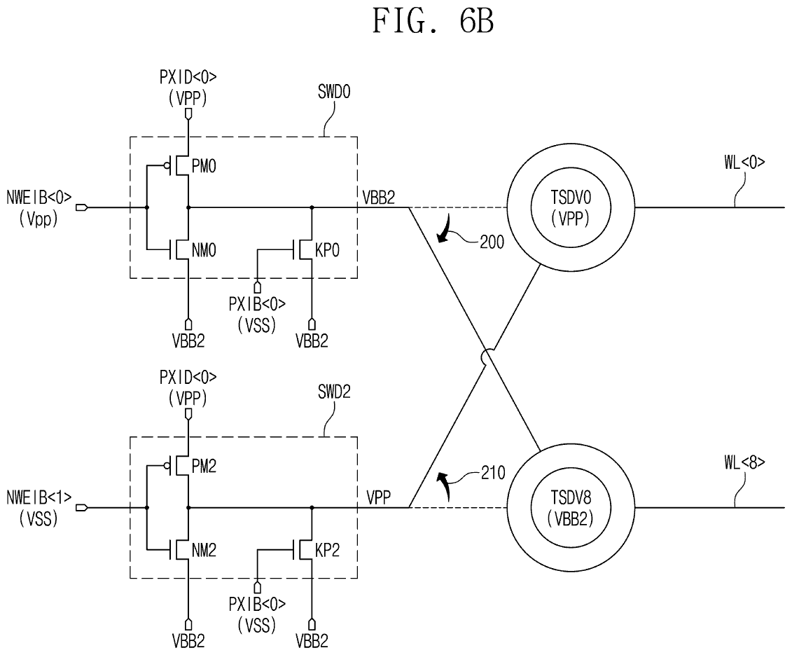

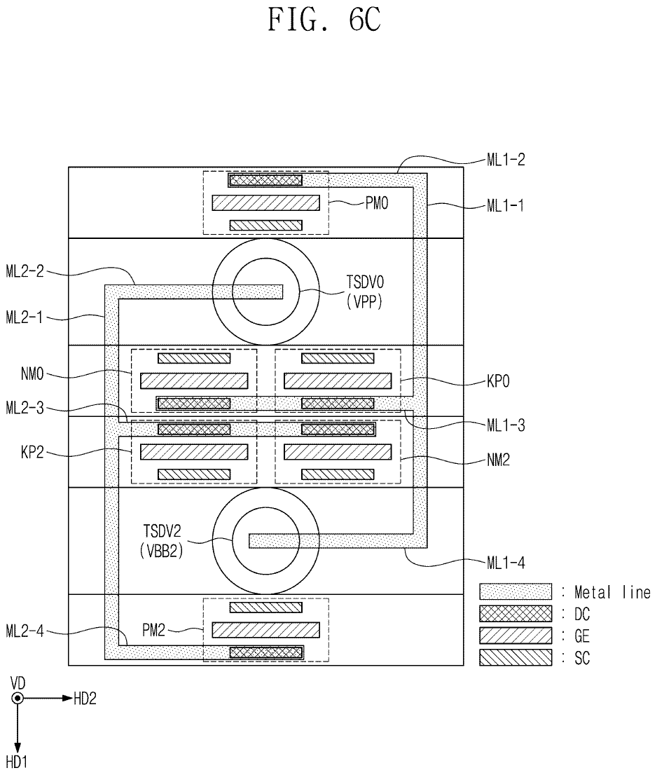

FIGS. 6A and 6B are diagrams illustrating a connection relationship between sub-wordline drivers and wordlines according to some implementations of the present disclosure. FIG. 6C is a diagram illustrating a connection relationship between sub-wordline drivers and vertical connection structures in the connection relationships of FIGS. 6A and 6B.

Referring to FIG. 6A, in implementations of the present disclosure, instead of a sub-wordline driver placed in a direction perpendicular to a connection pad connected to a wordline to be driven, any other sub-wordline driver may drive the wordline. In FIGS. 5A and 6A, components which are marked by the same reference numerals/signs may perform the same or similar functions, and thus, additional description will be omitted to avoid redundancy.

For example, the sub-wordline driver SWD2 may be placed in a direction perpendicular to a connection pad connected to the wordline WL<2> and may activate the wordline WL<0> through the vertical connection structure TSDV0, and the sub-wordline driver SWD0 may be placed in a direction perpendicular to a connection pad connected to the wordline WL<0> and may deactivate the wordline WL<2> through the vertical connection structure TSDV2.

In FIG. 6A, the sub-wordline drivers SWD0 and SWD2 may share the wordline enable signal NWEIB<0>, and the source terminals of the pull-up transistors PM0 and PM2 may respectively receive different control signals (e.g., PXID<0> and PXID<2>).

Referring to FIG. 6B, in implementations of the present disclosure, the sub-wordline drivers SWD0 and SWD2 may be configured such that the source terminals of the pull-up transistors PM0and PM2 share a control signal (e.g., PXID<0>) and to respectively receive different wordline enable signals NWEIB<0> and NWEIB<1>.

Referring to FIGS. 6A and 6C, even though the vertical connection structure TSDV0 has the voltage level VPP, because a sub-wordline driver connected to the vertical connection structure TSDV0 through metal lines (e.g., ML2-1, ML2-2, ML2-3, and ML2-4) is not the sub-wordline driver SWD0 but the sub-wordline driver SWD2, the sub-wordline driver SWD2 may be spaced apart from the vertical connection structure TSDV0 as much as a given distance. Even though the vertical connection structure TSDV2 has the voltage level VBB2, because a sub-wordline driver connected to the vertical connection structure TSDV2 through metal lines (e.g., ML1-1, ML1-2, ML1-3, and ML1-4) is not the sub-wordline driver SWD2 but the sub-wordline driver SWD0, the sub-wordline driver SWD0 may be spaced apart from the vertical connection structure TSDV2 as much as a given distance. Also, because the metal line ML1-3 having the voltage level VBB2 is placed between the pull-down transistor NM2 and the keeping transistor KP2 of the sub-wordline driver SWD2 and the vertical connection structure TSDV0, the shielding effect resisting the voltage level of the vertical connection structure TSDV0 may be obtained. Because the metal line ML2-3 having the voltage level VPP is placed between the pull-down transistor NM0 and the keeping transistor KP0 of the sub-wordline driver SWD0 and the vertical connection structure TSDV2, the shielding effect resisting the voltage level of the vertical connection structure TSDV2 may be obtained. Some implementations in which a vertical connection structure and a sub-wordline driver are connected through a plurality of metal lines is described with reference to FIG. 6C, but this is provided for convenience of description. Actually, two or more metal lines may be disposed in the same layer (or at the same vertical level) of a semiconductor memory device to form a portion of one metal line. For example, the metal lines ML1-1 to ML1-4 may be formed of one metal line, and the metal lines ML2-1 to ML2-4 may be formed of one metal line. In some implementations, a sub-wordline driver which activates or deactivates a wordline through the vertical connection structure TSDV2 may include the plurality of MOS transistors PM0, NM0, and KP0. A drain contact DC of each of the plurality of MOS transistors PM0, NM0, and KP0 may be connected to an end of the vertical connection structure TSDV2. For example, the drain contact DC of each of the plurality of MOS transistors PM0, NM0, and KP0 may be connected to the end of the vertical connection structure TSDV2 through a plurality of metal lines including the metal line ML1-1 extending in the horizontal direction HD1 and the metal lines ML1-2, ML1-3, and ML1-4 extending in the horizontal direction HD2. For example, the metal line ML1-4 may connect the metal line ML1-1 and the end of the vertical connection structure TSDV2. For example, the metal line ML1-3 may connect the metal line ML1-1 and the drain contacts DCs of the transistors NM0 and KP0.

In some implementations, a sub-wordline driver which activates or deactivates a wordline through the vertical connection structure TSDV0 may include the plurality of MOS transistors PM2, NM2, and KP2. A drain contact DC of each of the plurality of MOS transistors PM2, NM2, and KP2 may be connected to an end of the vertical connection structure TSDV0. For example, the drain contact DC of each of the plurality of MOS transistors PM2, NM2, and KP2 may be connected to the end of the vertical connection structure TSDV0 through a plurality of metal lines including the metal line ML2-1 extending in the horizontal direction HD1 and the metal lines ML2-2, ML2-3, and ML2-4 extending in the horizontal direction HD2. For example, the metal line ML2-2 may connect the metal line ML2-1 and the end of the vertical connection structure TSDV0. For example, the metal line ML2-3 may connect the metal line ML2-1 and the drain contacts DCs of the transistors KP2 and NM2.

In some implementations, the end of the vertical connection structure TSDV0 may be placed on one side of the plurality of MOS transistors PM0, NM0, and KP0, and the end of the vertical connection structure TSDV2 may be placed on one side of the plurality of MOS transistors PM2, NM2, and KP2.

In some implementations, the end of the vertical connection structure TSDV0 and the end of the vertical connection structure TSDV2 may be disposed on a virtual line extending in the horizontal direction HD1 with respect to the transistor PM0 or PM2.

In some implementations, the drain contacts DCs, gate contacts GEs, and source contacts SCs of the transistors PM0, NM0, KP0, PM2, NM2, and KP2 may extend in the horizontal direction HD2.

FIGS. 7 and 8 are flowcharts illustrating an operating method of a semiconductor memory device according to some implementations of the present disclosure.

In FIGS. 7 and 8, an operating method of a semiconductor memory device may be performed based on the sub-wordline drivers described with reference to FIGS. 1 to 3, 6A, 6B, and 6C.

Referring to FIG. 7, a read command and a read address may be received (S100).

In some implementations, the semiconductor memory device may include a first semiconductor die and a second semiconductor die stacked on the first semiconductor die in a vertical direction. The first semiconductor die may include a first connection pad, a second connection pad, a first wordline electrically connected to the first connection pad, and a second wordline electrically connected to the second connection pad. The second semiconductor die may include a first sub-wordline driver disposed to be spaced apart from the first connection pad in the vertical direction and a second sub-wordline driver disposed to be spaced apart from the second connection pad in the vertical direction.

In some implementations, the semiconductor memory device may operate under control of an external host device.

The second sub-wordline driver may activate the first wordline, based on wordline driving information WLDI (S110).

In some implementations, the wordline driving information WLDI may include information about connection relationships between a plurality of sub-wordline drivers and a plurality of wordlines of the semiconductor memory device. For example, the wordline driving information WLDI may indicate whether to use any sub-wordline driver to activate or deactivate any wordline.

A subsequent operation following the activation of the first wordline may be performed (S130).

In some implementations, the subsequent operation may include operations in which a sense amplifier circuit or a data input/output circuit of the semiconductor memory device outputs data read through the first wordline to the outside.

The first sub-wordline driver may activate the second wordline, based on the wordline driving information WLDI (S150).

A subsequent other operations following the activation of the second wordline may be performed (S170).

A read operation which is based on the read command may be completed (S190).

Referring to FIG. 8, a write command, a write address, and write data may be received (S300).

The second sub-wordline driver may activate the first wordline, based on the wordline driving information WLDI (S310).

A subsequent operation following the activation of the first wordline may be performed (S330).

In some implementations, the subsequent operation may include operations in which the data input/output circuit and the sense amplifier circuit of the semiconductor memory device write the pieces of received data in memory cells connected to the first wordline through the first wordline.

The first sub-wordline driver may activate the second wordline, based on the wordline driving information WLDI (S350).

A subsequent operation following the activation of the second wordline may be performed (S370).

A write operation which is based on the write command may be completed (S390).

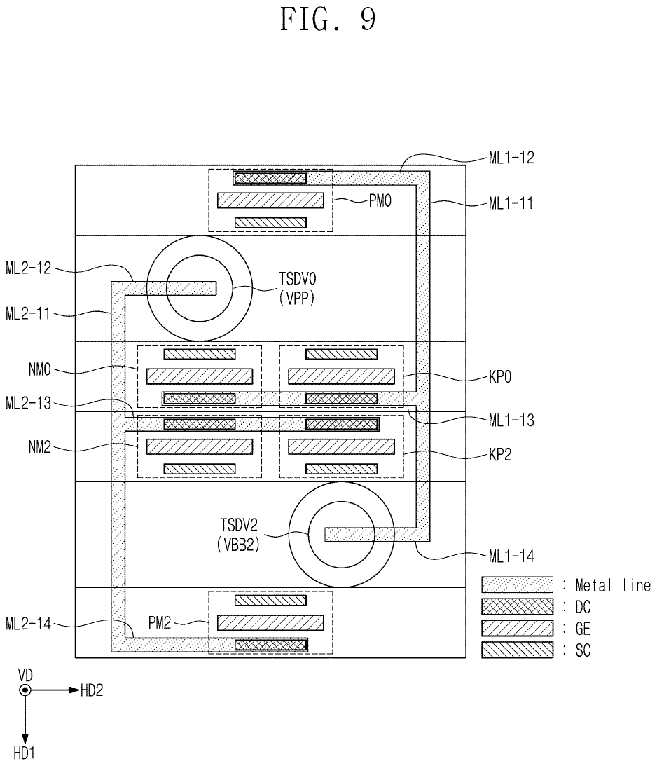

FIGS. 9, 10, 11, 12, 13, 14, 15, and 16 are diagrams illustrating a connection relationship between sub-wordline drivers and vertical connection structures in a semiconductor memory device according to some implementations of the present disclosure.

Each of implementations illustrated in FIGS. 9 to 16 may correspond to the implementations illustrated in FIG. 6C, and components which have the same reference numerals/signs as the components TSDV0, PM0, NM0, KP0, TSDV2, PM2, NM2, and KP2 illustrated in FIG. 6C may have the same functions, and thus, additional description will be omitted to avoid redundancy.

Referring to FIG. 9, a sub-wordline driver which activates or deactivates a wordline through the vertical connection structure TSDV2 may include the plurality of MOS transistors PM0, NM0, and KP0.

The drain contact DC of each of the plurality of MOS transistors PM0, NM0, and KP0 may be connected to the end of the vertical connection structure TSDV2. For example, the drain contact DC of each of the plurality of MOS transistors PM0, NM0, and KP0 may be connected to the end of the vertical connection structure TSDV2 through a plurality of metal lines including the metal line ML1-11 extending in the horizontal direction HD1 and the metal lines ML1-12, ML1-13, and ML1-14 extending in the horizontal direction HD2. For example, the metal line ML1-14 may connect the metal line ML1-11 and the end of the vertical connection structure TSDV2. For example, the metal line ML1-13 may connect the metal line ML1-11 and the drain contacts DCs of the transistors NM0 and KP0.

A sub-wordline driver which activates or deactivates a wordline through the vertical connection structure TSDV0 may include the plurality of MOS transistors PM2, NM2, and KP2. The drain contact DC of each of the plurality of MOS transistors PM2, NM2, and KP2 may be connected to the end of the vertical connection structure TSDV0. For example, the drain contact DC of each of the plurality of MOS transistors PM2, NM2, and KP2 may be connected to the end of the vertical connection structure TSDV0 through a plurality of metal lines including a metal line ML2-11 extending in the horizontal direction HD1 and metal lines ML2-12, ML2-13, and ML2-14 extending in the horizontal direction HD2. For example, the metal line ML2-12 may connect the metal line ML2-11 and the end of the vertical connection structure TSDV0. For example, the metal line ML2-13 may connect the metal line ML2-11 and the drain contacts DCs of the transistors KP2 and NM2.

In some implementations, the end of the vertical connection structure TSDV0 may be disposed on a virtual line extending in the horizontal direction HD1 with respect to the transistor NM0. The vertical connection structure TSDV2 may be disposed on a virtual line extending in the horizontal direction HD1 with respect to the transistor NM2.

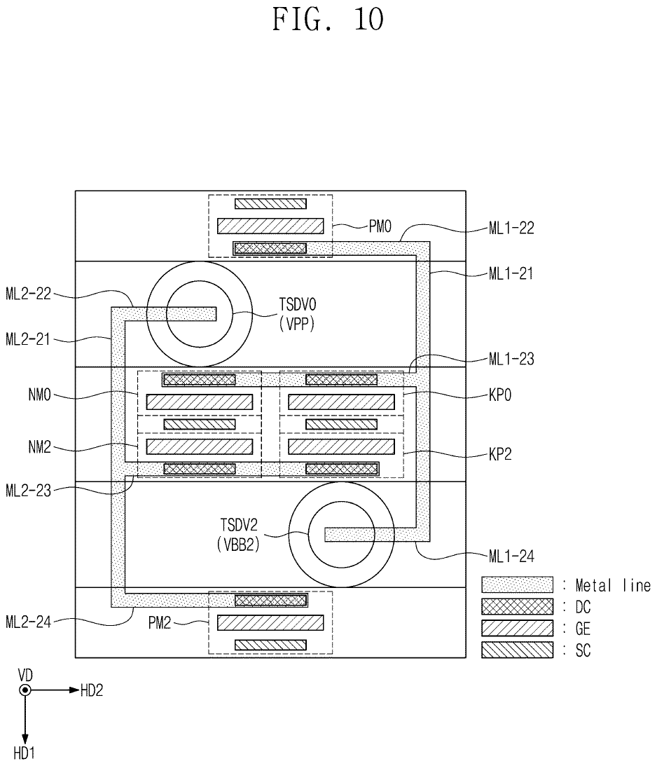

Referring to FIG. 10, a sub-wordline driver which activates or deactivates a wordline through the vertical connection structure TSDV2 may include the plurality of MOS transistors PM0, NM0, and KP0.

The drain contact DC of each of the plurality of MOS transistors PM0, NM0, and KP0 may be connected to the end of the vertical connection structure TSDV2. For example, the drain contact DC of each of the plurality of MOS transistors PM0, NM0, and KP0 may be connected to the end of the vertical connection structure TSDV2 through a plurality of metal lines including a metal line ML1-21 extending in the horizontal direction HD1 and metal lines ML1-22, ML1-23, and ML1-24 extending in the horizontal direction HD2. For example, the metal line ML1-24 may connect the metal line ML1-21 and the end of the vertical connection structure TSDV2. For example, the metal line ML1-23 may connect the metal line ML1-21 and the drain contacts DCs of the transistors NM0 and KP0.

A sub-wordline driver which activates or deactivates a wordline through the vertical connection structure TSDV0 may include the plurality of MOS transistors PM2, NM2, and KP2. The drain contact DC of each of the plurality of MOS transistors PM2, NM2, and KP2 may be connected to the end of the vertical connection structure TSDV0. For example, the drain contact DC of each of the plurality of MOS transistors PM2, NM2, and KP2 may be connected to the end of the vertical connection structure TSDV0 through a plurality of metal lines including a metal line ML2-21 extending in the horizontal direction HD1 and metal lines ML2-22, ML2-23, and ML2-24 extending in the horizontal direction HD2. For example, the metal line ML2-22 may connect the metal line ML2-21 and the end of the vertical connection structure TSDV0. For example, the metal line ML2-23 may connect the metal line ML2-21 and the drain contacts DCs of the transistors KP2 and NM2.

In some implementations, the end of the vertical connection structure TSDV0 may be disposed on a virtual line extending in the horizontal direction HD1 with respect to the transistor NM0. The vertical connection structure TSDV2 may be disposed on a virtual line extending in the horizontal direction HD1 with respect to the transistor NM2.

In some implementations, unlike the implementations illustrated in FIG. 9, the source contacts SCs or source regions of the transistors NM0 and NM2 may be mutually shared, and the source contacts SCs or source regions of the transistors KP0 and KP2 may be mutually shared. For example, compared to the implementations illustrated in FIG. 9, the drain contact DC or the source contact SC of each of the transistors NM0, KP0, PM0, NM2, KP2, and PM2 of FIG. 10 may be disposed at locations mutually switched with respect to the gate electrode GE.

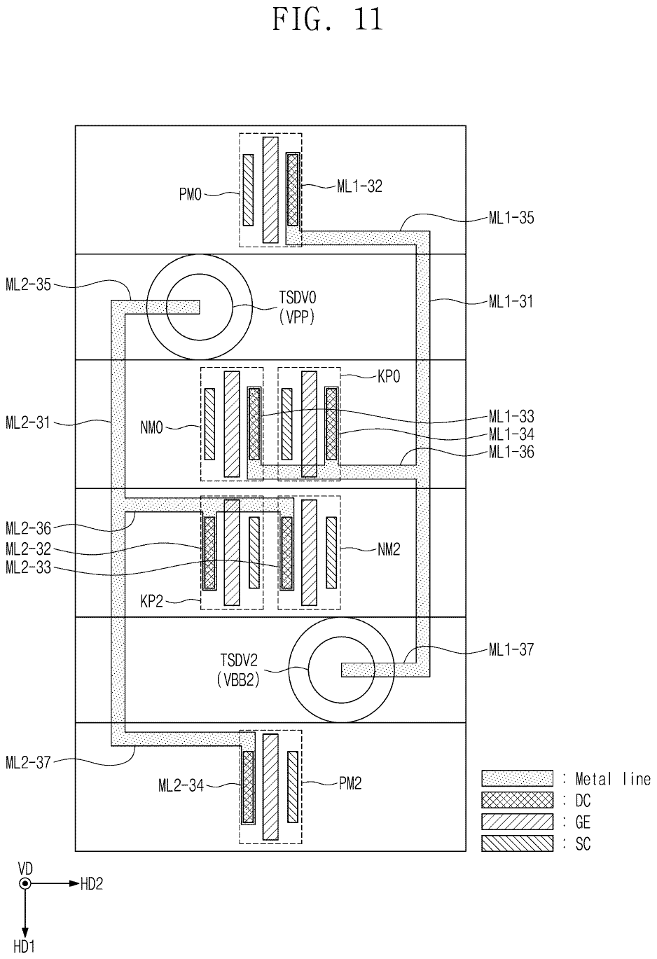

Referring to FIG. 11, a sub-wordline driver which activates or deactivates a wordline through the vertical connection structure TSDV2 may include the plurality of MOS transistors PM0, NM0, and KP0.

The drain contact DC of each of the plurality of MOS transistors PM0, NM0, and KP0 may be connected to the end of the vertical connection structure TSDV2. For example, the drain contact DC of each of the plurality of MOS transistors PM0, NM0, and KP0 may be connected to the end of the vertical connection structure TSDV2 through a plurality of metal lines including metal lines ML1-31, ML1-32, ML1-33, and ML1-34 extending in the horizontal direction HD1 and metal lines ML1-35, ML1-36, and ML1-37 extending in the horizontal direction HD2. For example, the metal line ML1-37 may connect the metal line ML1-31 and the end of the vertical connection structure TSDV2. For example, the metal lines ML1-33, ML1-34, and ML1-36 may connect the metal line ML1-31 and the drain contacts DCs of the transistors NM0 and KP0.

A sub-wordline driver which activates or deactivates a wordline through the vertical connection structure TSDV0 may include the plurality of MOS transistors PM2, NM2, and KP2. The drain contact DC of each of the plurality of MOS transistors PM2, NM2, and KP2 may be connected to the end of the vertical connection structure TSDV0. For example, the drain contact DC of each of the plurality of MOS transistors PM2, NM2, and KP2 may be connected to the end of the vertical connection structure TSDV0 through a plurality of metal lines including metal lines ML2-31, ML2-32, ML2-33, and ML2-34 extending in the horizontal direction HD1 and metal lines ML2-35, ML2-36, and ML2-37 extending in the horizontal direction HD2. For example, the metal line ML2-35 may connect the metal line ML2-21 and the end of the vertical connection structure TSDV0. For example, the metal lines ML2-32, ML2-33, and ML-36 may connect the metal line ML2-31 and the drain contacts DCs of the transistors KP2 and NM2.

In some implementations, unlike the implementations illustrated in FIGS. 6C, 9, or 10, the drain contacts DCs, the gate contacts GEs, and the source contacts SCs of the transistors PM0, NM0, KP0, PM2, NM2, and KP2 may extend in the horizontal direction HD1.

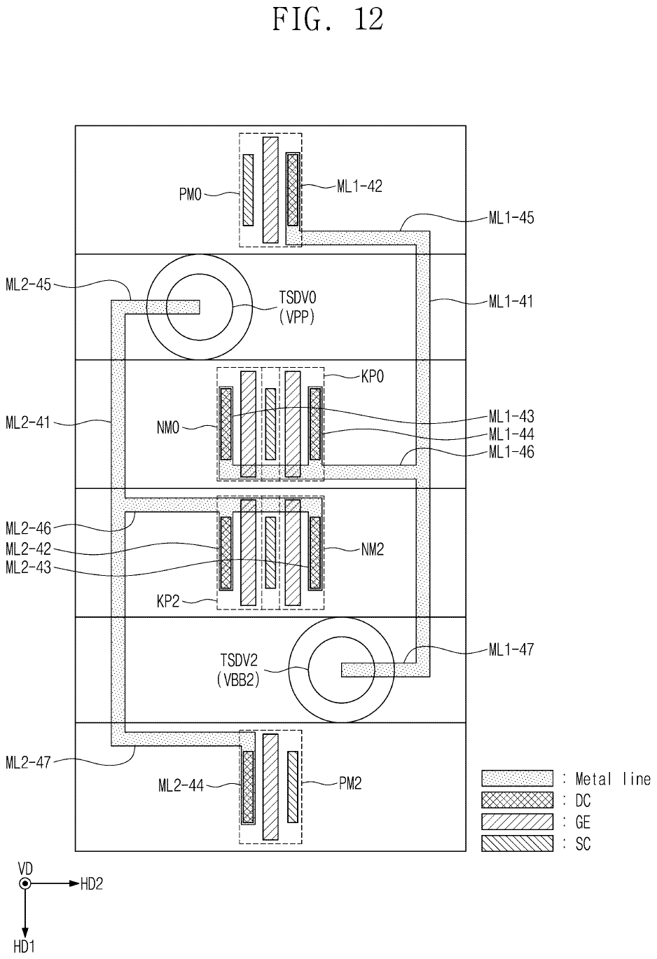

Referring to FIG. 12, a sub-wordline driver which activates or deactivates a wordline through the vertical connection structure TSDV2 may include the plurality of MOS transistors PM0, NM0, and KP0.

The drain contact DC of each of the plurality of MOS transistors PM0, NM0, and KP0 may be connected to the end of the vertical connection structure TSDV2. For example, the drain contact DC of each of the plurality of MOS transistors PM0, NM0, and KP0 may be connected to the end of the vertical connection structure TSDV2 through a plurality of metal lines including metal lines ML1-41, ML1-42, ML1-43, and ML1-44 extending in the horizontal direction HD1 and metal lines ML1-45, ML1-46, and ML1-47 extending in the horizontal direction HD2.

A sub-wordline driver which activates or deactivates a wordline through the vertical connection structure TSDV0 may include the plurality of MOS transistors PM2, NM2, and KP2. The drain contact DC of each of the plurality of MOS transistors PM2, NM2, and KP2 may be connected to the end of the vertical connection structure TSDV0. For example, the drain contact DC of each of the plurality of MOS transistors PM2, NM2, and KP2 may be connected to the end of the vertical connection structure TSDV0 through a plurality of metal lines including metal lines ML2-41, ML2-42, ML2-43, and ML2-44 extending in the horizontal direction HD1 and metal lines ML2-45, ML2-46, and ML2-47 extending in the horizontal direction HD2.

In some implementations, unlike the implementations illustrated in FIG. 11, the source contacts SCs or source regions of the transistors NM0 and KP0 may be mutually shared, and the source contacts SCs or source regions of the transistors NM2 and KP2 may be mutually shared.

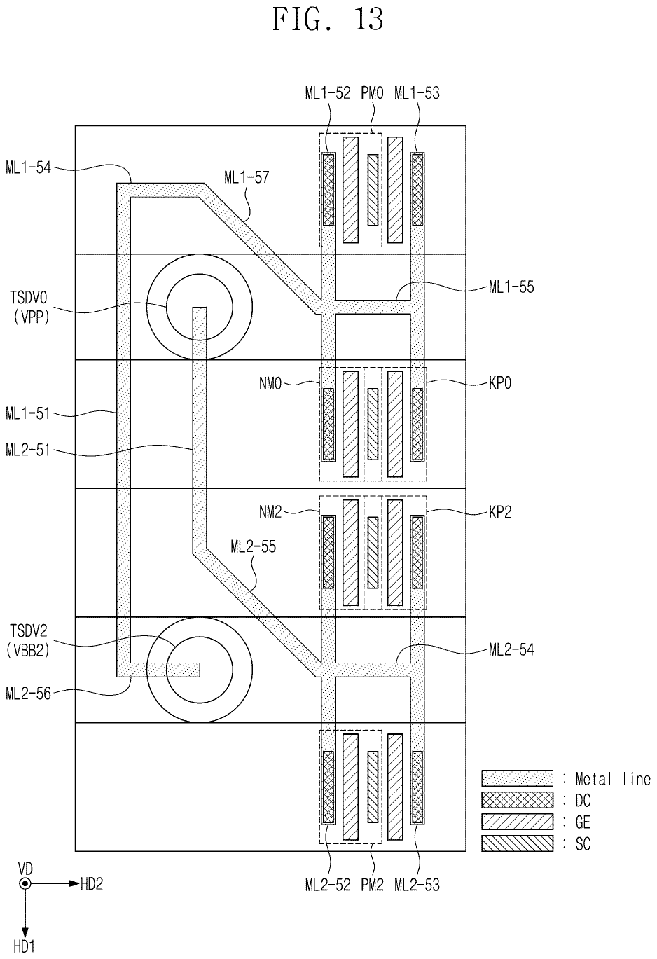

Referring to FIG. 13, a sub-wordline driver which activates or deactivates a wordline through the vertical connection structure TSDV2 may include the plurality of MOS transistors PM0, NM0, and KP0.

The drain contact DC of each of the plurality of MOS transistors PM0, NM0, and KP0 may be connected to the end of the vertical connection structure TSDV2. For example, the drain contact DC of each of the plurality of MOS transistors PM0, NM0, and KP0 may be connected to the end of the vertical connection structure TSDV2 through a plurality of metal lines including metal lines ML1-51, ML1-52, and ML1-53 extending in the horizontal direction HD1, metal lines ML1-54, ML1-55, ML1-56 extending in the horizontal direction HD2, and a metal line ML1-57 obliquely extending between the horizontal directions HD1 and HD2. For example, the metal line ML1-56 may connect the metal line ML1-51 and the end of the vertical connection structure TSDV2. For example, the metal lines ML1-52 and ML1-53 may connect the metal line ML1-55 and the drain contacts DCs of the transistors NM0 and KP0.

A sub-wordline driver which activates or deactivates a wordline through the vertical connection structure TSDV0 may include the plurality of MOS transistors PM2, NM2, and KP2. The drain contact DC of each of the plurality of MOS transistors PM2, NM2, and KP2 may be connected to the end of the vertical connection structure TSDV0. For example, the drain contact DC of each of the plurality of MOS transistors PM2, NM2, and KP2 may be connected to the end of the vertical connection structure TSDV0 through a plurality of metal lines including metal lines ML2-51, ML2-52, and ML2-53 extending in the horizontal direction HD1, a metal line ML2-54 extending in the horizontal direction HD2, and a metal line ML2-55 obliquely extending between the horizontal directions HD1 and HD2. For example, the metal line ML2-51 may connect the metal line ML2-55 and the end of the vertical connection structure TSDV0. For example, the metal lines ML2-52 and ML2-53 may connect the metal line ML2-54 and the drain contacts DCs of the transistors NM2 and KP2.

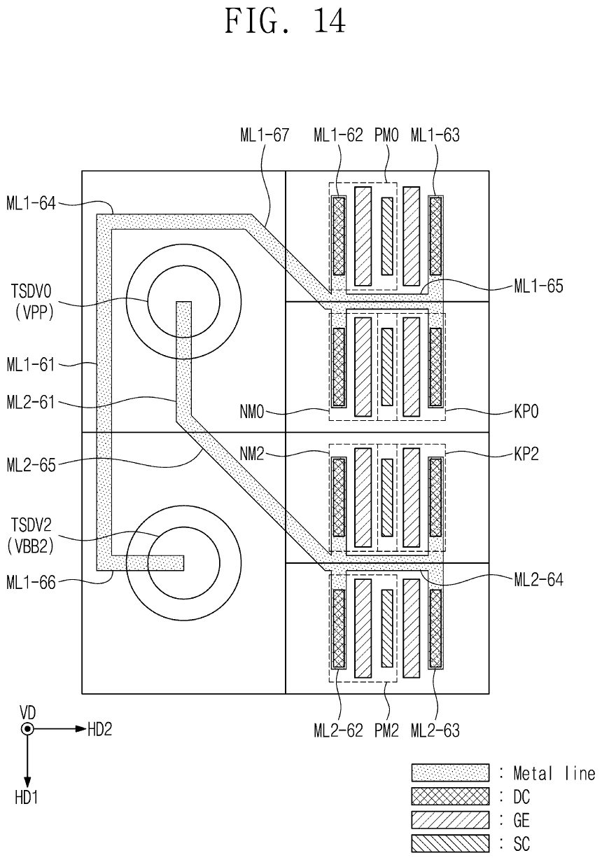

Referring to FIG. 14, a sub-wordline driver which activates or deactivates a wordline through the vertical connection structure TSDV2 may include the plurality of MOS transistors PM0, NM0, and KP0.

The drain contact DC of each of the plurality of MOS transistors PM0, NM0, and KP0 may be connected to the end of the vertical connection structure TSDV2. For example, the drain contact DC of each of the plurality of MOS transistors PM0, NM0, and KP0 may be connected to the end of the vertical connection structure TSDV2 through a plurality of metal lines including metal lines ML1-61, ML1-62, and ML1-63 extending in the horizontal direction HD1, metal lines ML1-64, ML1-65, ML1-66 extending in the horizontal direction HD2, and a metal line ML1-67 obliquely extending between the horizontal directions HD1 and HD2.

A sub-wordline driver which activates or deactivates a wordline through the vertical connection structure TSDV0 may include the plurality of MOS transistors PM2, NM2, and KP2. The drain contact DC of each of the plurality of MOS transistors PM2, NM2, and KP2 may be connected to the end of the vertical connection structure TSDV0. For example, the drain contact DC of each of the plurality of MOS transistors PM2, NM2, and KP2 may be connected to the end of the vertical connection structure TSDV0 through a plurality of metal lines including metal lines ML2-61, ML2-62, and ML2-63, extending in the horizontal direction HD1 and metal line ML2-64, extending in the horizontal direction HD2 and metal line ML2-65 obliquely extending between the horizontal directions HD1 and HD2.

In some implementations, compared to the implementations illustrated in FIG. 13, a region between the MOS transistor PM0 and the MOS transistors NM0 and KP0 may be reduced, and a region between the MOS transistor PM2 and the MOS transistors NM2 and KP2 may be reduced. For example, it may be possible to decrease lengths of the metal lines ML1-62 and ML1-63 or lengths of the metal lines ML2-62 and ML2-63, and it may also be possible to decrease the area of sub-wordline drivers.

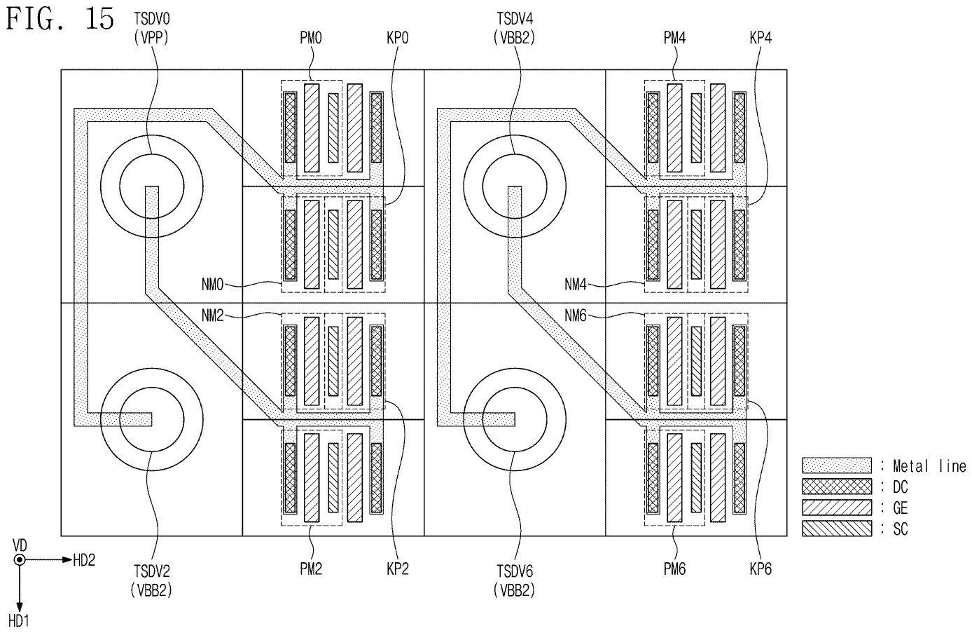

Referring to FIG. 15, some implementations illustrated in FIG. 15 may repeatedly include the pattern of the implementations illustrated in FIG. 14.

In some implementations, sub-wordline drivers activating or deactivating wordlines through the vertical connection structures TSDV0 and TSDV2 may have the same connection relationship or wiring relationship with sub-wordline drivers activating or deactivating wordlines through vertical connection structures TSDV4 and TSDV6.

In some implementations, metal lines for connecting the MOS transistors PM0, NM0, and KP0 and the vertical connection structure TSDV2 may be identical or similar in shape to metal lines for connecting MOS transistors PM4, NM4, and KP4 and the vertical connection structure TSDV6. Metal lines for connecting the MOS transistors PM2, NM2, and KP2 and the vertical connection structure TSDV0 may be identical or similar in shape to metal lines for connecting MOS transistors PM6, NM6, and KP6 and the vertical connection structure TSDV4.

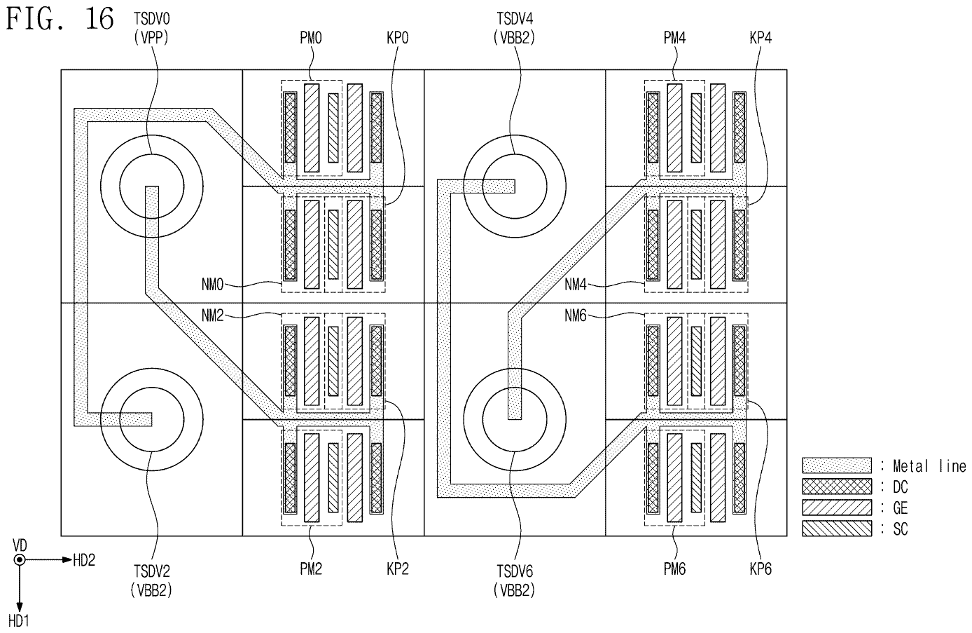

Referring to FIG. 16, some implementations illustrated in FIG. 16 may repeatedly include the pattern of the implementations illustrated in FIG. 14, and one (e.g., a second pattern) of the patterns (e.g., a first pattern and a second pattern) repeatedly included may be implemented by rotating the first pattern as much as 180 degrees by using a virtual line extending in the horizontal direction HD2 as a central axis.

In some implementations, sub-wordline drivers (e.g., first sub-wordline drivers) activating or deactivating wordlines through the vertical connection structures TSDV0 and TSDV2 may have a connection relationship or a wiring relationship similar to that of sub-wordline drivers (e.g., second sub-wordline drivers) activating or deactivating wordlines through the vertical connection structures TSDV4 and TSDV6, and the second sub-wordline drivers may have a pattern (or a shape) which is implemented by rotating the pattern or (the shape) of the first sub-wordline drivers as much as 180 degrees by using a virtual line extending in the horizontal direction HD2 as a central axis.

In some implementations, metal lines (e.g., first metal lines) for connecting the MOS transistors PM0, NM0, and KP0 and the vertical connection structure TSDV2 may be similar in pattern or shape to metal lines (e.g., second metal lines) for connecting the MOS transistors PM6, NM6, and KP6 and the vertical connection structure TSDV4, and the pattern or shape of the second metal lines may correspond to a pattern or shape that is rotated 180 degrees from the pattern or shape of the first metal lines with respect to a virtual line extending in the horizontal direction HD2. Metal lines (e.g., third metal lines) for connecting the MOS transistors PM2, NM2, and KP2 and the vertical connection structure TSDV0 may be similar in pattern or shape to metal lines (e.g., fourth metal lines) for connecting MOS transistors PM4, NM4, and KP4 and the vertical connection structure TSDV6, and the pattern or shape of the fourth metal lines may correspond to a pattern or shape that is rotated 180 degrees from the pattern or shape of the third metal lines with respect to a virtual line extending in the horizontal direction (HD2).

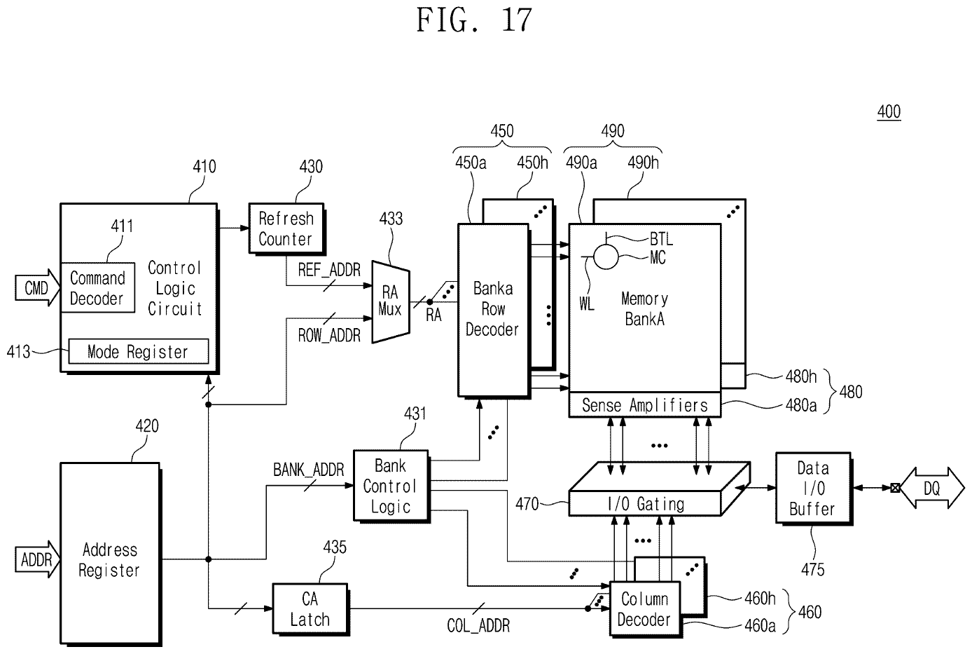

FIG. 17 is a block diagram illustrating some implementations of a semiconductor memory device of FIG. 1.

Referring to FIG. 17, a memory device 400 may include a control logic circuit 410, an address register 420, bank control logic 431, a row address multiplexer 433, a column address latch 435, a row decoder 450, a column decoder 460, a memory cell array 490, an input/output gating circuit 470, a sense amplifier unit 480, a data input/output buffer 475, and a refresh counter 430.

The memory cell array 490 may include first to eighth memory banks 490a to 490h. The row decoder 450 may include first to eighth bank row decoders 450a to 450h respectively connected to the first to eighth memory banks 490a to 490h, the column decoder 460 may include first to eighth bank column decoders 460a to 460h respectively connected to the first to eighth memory banks 490a to 490h, and the sense amplifier unit 480 may include first to eighth bank sense amplifiers 480a to 480h respectively connected to the first to eighth memory banks 490a to 490h.

The first to eighth memory banks 490a to 490h, the first to eighth bank sense amplifiers 480a to 480h, the first to eighth bank row decoders 450a to 450h, and the first to eighth bank column decoders 460a to 460h may constitute first to eighth banks. Each of the first to eighth memory banks 490a to 490h may include a plurality of wordlines WLs, a plurality of bitlines BLs, and a plurality of memory cells MCs formed at intersections of the wordlines WLs and the bitlines BLs.

An example of the memory device 400 including eight banks is illustrated in FIG. 17. However, in other implementations, the memory device 400 may include banks, the number of which is 2 or more.

The address register 420 may receive an address ADDR including a bank address BANK_ADDR, a row address ROW_ADDR, and a column address COL_ADDR from a memory controller. The address register 420 may provide the received bank address BANK_ADDR to the bank control logic 431, may provide the received row address ROW_ADDR to the row address multiplexer 433, and may provide the received column address COL_ADDR to the column address latch 435.

The bank control logic 431 may generate bank control signals in response to the bank address BANK_ADDR. A bank row decoder corresponding to the bank address BANK_ADDR from among the first to eighth bank row decoders 450a to 450h may be activated in response to the bank control signals, and a bank column decoder corresponding to the bank address BANK_ADDR from among the first to eighth bank column decoders 460a to 460h may be activated in response to the bank control signals.

The row address multiplexer 433 may receive the row address ROW_ADDR from the address register 420 and may receive a refresh row address REF_ADDR from the refresh counter 430. The row address multiplexer 433 may selectively output the row address ROW_ADDR or the refresh row address REF_ADDR as a row address RA. The row address RA output from the row address multiplexer 433 may be applied to each of the first to eighth bank row decoders 450a to 450h.

A bank row decoder activated by the bank control logic 431 from among the first to eighth bank row decoders 450a to 450h may decode the row address RA output from the row address multiplexer 433 and may activate a word line corresponding to the row address RA. For example, the activated bank row decoder may apply a word line driving voltage to the word line corresponding to the row address RA. The activated bank row decoder may generate the word line driving voltage by using a power supply voltage and may provide the word line driving voltage to the corresponding word line.

The column address latch 435 may receive the column address COL_ADDR from the address register 420 and may temporarily store the received column address COL_ADDR. Also, in a burst mode, the column address latch 435 may gradually (or sequentially) increase the received column address COL_ADDR. The column address latch 435 may apply the temporarily stored column address COL_ADDR or the gradually increased column address COL_ADDR to each of the first to eighth bank column decoders 460a to 460h.

A bank column decoder activated by the bank control logic 431 from among the first to eighth bank column decoders 460a to 460h may activate a sense amplifier corresponding to the bank address BANK_ADDR and the column address COL_ADDR through the input/output gating circuit 470.

The input/output gating circuit 470 may include the following together with circuits gating input/output data: input data mask logic, read data latches for storing data output from the first to eighth memory banks 490a to 490h, and write drivers for writing data in the first to eighth memory banks 490a to 490h.

Data read from one memory bank among the first to eighth memory banks 490a to 490h may be sensed by a sense amplifier corresponding to the one memory bank and may be stored in the read data latches.

The data stored in the read data latches may be provided to the memory controller through the data input/output buffer 475. Data DQ to be written in one memory bank among the first to eighth memory banks 490a to 490h may be provided to the data input/output buffer 475 from the memory controller. The data DQ provided to the data input/output buffer 475 may be provided to the input/output gating circuit 470.

The control logic circuit 410 may control the operation of the memory device 400. For example, the control logic circuit 410 may generate control signals such that the memory device 400 performs the write operation or the read operation. The control logic circuit 410 may include a command decoder 411 that decodes a command CMD received from the memory controller and a mode register 413 for setting an operation mode of the memory device 400.

In some implementations, the memory devices according to implementations of the present disclosure described with reference to FIG. 1 may correspond to the memory device 400.

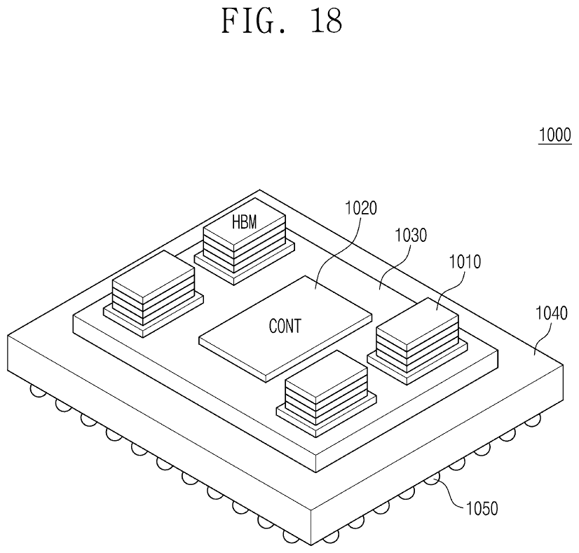

FIG. 18 is a structure diagram illustrating some implementations of a semiconductor package including a semiconductor memory device according to implementations of the present disclosure.

Referring to FIG. 18, a semiconductor package 1000 may include one or more stack-type memory devices 1010 and a memory controller 1020. The stack-type memory device 1010 and the memory controller 1020 may be mounted on an interposer 1030, and the interposer 1030 on which the stack-type memory device 1010 and the memory controller 1020 are mounted may be mounted on a package substrate 1040. The memory controller 1020 may correspond to a semiconductor device capable of controlling a function of the stack-type memory device 1010. For example, the memory controller 1020 may be implemented with an application processor (AP).

The stack-type memory device 1010 may be implemented in various shapes. According to some implementations, the stack-type memory device 1010 may be a memory device that is implemented in the shape of a high bandwidth memory where a plurality of layers are stacked. Accordingly, the stack-type memory device 1010 may include a buffer die and a plurality of memory dies, and one or more of the plurality of memory dies may be implemented with a memory device according to implementations of the present disclosure described with reference to FIG. 1.

The plurality of stack-type memory devices 1010 may be mounted on the interposer 1030, and the memory controller 1020 may communicate with the plurality of stack-type memory devices 1010. Herein, the interposer 1030 may include a TSV-type or PCB-type organic or a non-TSV-type embedded multi-die interconnect bridge (EMIB).

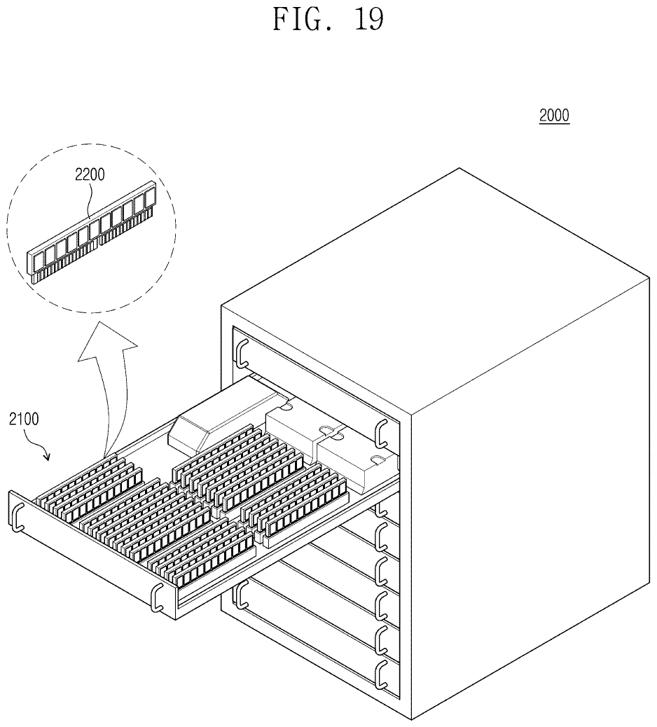

FIG. 19 is a conceptual diagram illustrating an electronic system including a semiconductor memory device according to implementations of the present disclosure.

Referring to FIG. 19, an electronic system 2000 may be a server system including a plurality of server racks. One server rack 2100 of the plurality of server racks is illustrated in FIG. 19 as an example.

Each of the plurality of server racks may include one or more memory systems. For example, the server rack 2100 may include one or more memory systems. The one or more memory systems may include a semiconductor memory device according to implementations of the present disclosure described with reference to FIG. 1. One or more memory modules 2200 included in the server rack 2100 are illustrated in FIG. 19.

The server rack 2100 may further include sub-wordline drivers, connection pads, and a vertical connection structure illustrated in FIG. 1, as well as the memory module 2200. The one or more memory systems may be connected to at least one processor included in the server rack 2100 without a chipset. For example, a memory system may be a volatile memory module implemented in the shape of a dual in-line memory module (DIMM). In this example, the one or more memory systems may be electrically connected to a DIMM socket electrically connected to the processor and may communicate with the processor. As an example, memory systems may communicate with a memory controller in compliance with the interface protocol which is defined in the DIMM specification and supports the DDR scheme, and the electronic system 2000 including the memory systems may communicate with an external host device through the CXL interface.

As described above, a semiconductor memory device according to implementations of the present disclosure may drive a wordline by using any other sub-wordline driver, not a sub-wordline driver located in a direction perpendicular to a connection pad connected to the wordline. Accordingly, the sub-wordline driver driving the wordline may be disposed to be spaced apart from one point in a direction perpendicular to the connection pad connected to the wordline to be driven such that a voltage level of the wordline to be driven is stabilized even though a voltage level of a vertical connection structure fluctuates.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A semiconductor memory device comprising:
a first semiconductor die; and
a second semiconductor die on the first semiconductor die in a vertical direction,
wherein the first semiconductor die includes:
a first connection pad;
a second connection pad;
a first wordline electrically connected to the first connection pad; and
a second wordline electrically connected to the second connection pad, and
wherein the second semiconductor die includes:
a first sub-wordline driver spaced apart from the first connection pad in the vertical direction; and
a second sub-wordline driver spaced apart from the second connection pad in the vertical direction, wherein the second sub-wordline driver is configured to drive the first wordline through the first connection pad.

2. The semiconductor memory device of claim 1, comprising:
a first vertical connection structure extending from the first connection pad in the vertical direction.

3. The semiconductor memory device of claim 2, wherein the second sub-wordline driver includes a plurality of second metal oxide semiconductor (MOS) transistors, and
wherein a drain contact of each of the plurality of second MOS transistors is connected to an end of the first vertical connection structure.

4. The semiconductor memory device of claim 3, wherein the first sub-wordline driver includes a plurality of first MOS transistors, and
wherein the end of the first vertical connection structure is on a side of the plurality of first MOS transistors.

5. The semiconductor memory device of claim 3, wherein the drain contact of each of the plurality of second MOS transistors is connected to the end of the first vertical connection structure through a plurality of metal lines.

6. The semiconductor memory device of claim 5, wherein the plurality of metal lines includes:
a first metal line extending in a first horizontal direction; and
a second metal line, a third metal line, and a fourth metal line extending in a second horizontal direction.

7. The semiconductor memory device of claim 6, wherein the second metal line connects the first metal line and the end of the first vertical connection structure.

8. The semiconductor memory device of claim 7, wherein the plurality of second MOS transistors includes:
a second pull-up transistor, a second pull-down transistor, and a second keeping transistor, and
wherein the third metal line connects the first metal line with drain contacts of the second keeping transistor and the second pull-down transistor.

9. The semiconductor memory device of claim 8, wherein the first vertical connection structure is on a virtual line extending in the first horizontal direction with respect to the second pull-down transistor.

10. The semiconductor memory device of claim 5, wherein the plurality of metal lines includes:
a first metal line, a second metal line, a third metal line, and a fourth metal line extending in a first horizontal direction; and
a fifth metal line, a sixth metal line, and a seventh metal line extending in a second horizontal direction.

11. The semiconductor memory device of claim 10, wherein the fifth metal line connects the first metal line with the end of the first vertical connection structure.

12. The semiconductor memory device of claim 11, wherein the plurality of second MOS transistors includes:
a second pull-up transistor, a second pull-down transistor, and a second keeping transistor, and
wherein the second metal line, the third metal line, and the sixth metal line connect the first metal line with drain contacts of the second keeping transistor and the second pull-down transistor.

13. The semiconductor memory device of claim 5, wherein the plurality of metal lines includes:
a first metal line, a second metal line, and a third metal line extending in a first horizontal direction;
a fourth metal line extending in a second horizontal direction; and
a fifth metal line obliquely extending between the first horizontal direction and the second horizontal direction.

14. The semiconductor memory device of claim 13, wherein the first metal line connects the fifth metal line with the end of the first vertical connection structure.

15. The semiconductor memory device of claim 14, wherein the second metal line, the third metal line, the fourth metal line, and the fifth metal line connect the first metal line with the drain contacts of the plurality of second MOS transistors.

16. An operating method of a semiconductor memory device, wherein the semiconductor memory device comprises:
a first semiconductor die, and
a second semiconductor die on the first semiconductor die in a vertical direction,
wherein the first semiconductor die includes a first connection pad, a second connection pad, a first wordline electrically connected to the first connection pad, and a second wordline electrically connected to the second connection pad, and
wherein the second semiconductor die includes a first sub-wordline driver spaced apart from the first connection pad in the vertical direction and a second sub-wordline driver spaced apart from the second connection pad in the vertical direction,
wherein the method comprises:
receiving a read command and a read address;
activating, using the second sub-wordline driver, the first wordline based on wordline driving information;
performing first subsequent operations after activating the first wordline; and
completing a read operation based on the read command.

17. The method of claim 16, wherein the semiconductor memory device includes:
a first vertical connection structure electrically connecting the second sub-wordline driver with the first connection pad.

18. The method of claim 17, wherein activating the first wordline includes:
pulling up, using the second sub-wordline driver, a voltage level of the first wordline through the first vertical connection structure and the first connection pad.

19. The method of claim 17, wherein the second sub-wordline driver includes a plurality of second MOS transistors, and
wherein a drain contact of each of the plurality of second MOS transistors is connected to an end of the first vertical connection structure.

20. An electronic system comprising:
a host device; and
a semiconductor memory device configured to operate under control of the host device,
wherein the semiconductor memory device includes:
a first semiconductor die; and
a second semiconductor die on the first semiconductor die in a vertical direction,
wherein the first semiconductor die includes:
a first connection pad;
a second connection pad;
a first wordline electrically connected to the first connection pad; and
a second wordline electrically connected to the second connection pad, and
wherein the second semiconductor die includes:
a first sub-wordline driver spaced apart from the first connection pad in the vertical direction; and
a second sub-wordline driver spaced apart from the second connection pad in the vertical direction, the second sub-wordline driver being configured to drive the first wordline through the first connection pad based on an access request from the host device.
